(19) United States
(12) Patent Application Publication
(10) Pub. No.: US 2026/0023896 A1
(43) Pub. Date: Jan. 22, 2026

(54) SELECTIVELY UPDATING MACHINE LEARNING MODEL PARAMETERS IN A TELECOMMUNICATIONS NETWORK

(71) Applicant: T-Mobile USA, Inc., Bellevue, WA (US)

(72) Inventors: George Frantz Cummings, Bellevue, WA (US); John Joseph Humbert, IV, Olathe, KS (US); Kun Lu, Bellevue, KS (US)

(21) Appl. No.: 18/777,351

(22) Filed: Jul. 18, 2024

(51) Int. Cl. G06F 30/27

(52) U.S. Cl. CPC G06F 30/27

(57) ABSTRACT

Systems and methods for configuring a network system to assign multiple user devices of a telecommunications network to a selected update group of a plurality of update groups. In some cases, the system comprises instructions to provide a data analysis model to the multiple user devices such that the data analysis model is usable by the multiple user devices to control performance of the multiple user devices, assign each of the multiple user devices to a selected update group of a plurality of update groups such that each respective user device is assigned to a corresponding selected update group based on a set of device environment parameters of the respective user device, detect an update event for the data analysis model, and selectively broadcast updated data samples for the data analysis model to user devices in a first update group of the plurality of update groups.

### BACKGROUND

In the field of machine learning (ML) and artificial intelligence (AI), a model is a mathematical method which, after being “trained” on a given dataset, can be used to identify patterns and/or make decisions from new unseen data. During training, a learning algorithm iteratively adjusts the model's internal parameters to minimize errors in its predictions. By extension, the model can refer to several levels of specificity, from a general class of models and their associated learning algorithms to a fully trained model with all its internal parameters tuned.

Typically, ML models require a high quantity of reliable data to perform accurate predictions. When training an ML model, engineers need to target and collect a large and representative sample of data. Data from the training set can be as varied as a corpus of text, a collection of images, sensor data, and data collected from individual users of a service.

### BRIEF DESCRIPTION OF THE DRAWINGS

Detailed descriptions of implementations of the present invention will be described and explained through the use of the accompanying drawings.

FIG. 1 is a block diagram that illustrates a wireless communications system that can implement aspects of the present technology.

FIG. 2 is a block diagram that illustrates components of a device grouping system in some implementations.

FIG. 3 is a block diagram that illustrates components of a user equipment device in some implementations.

FIG. 4 is a block diagram that illustrates components of a network server in some implementations.

FIG. 5 is a flow diagram that illustrates a process to configure a network system in some implementations.

FIG. 6 is a flow diagram that illustrates another process to configure a network system in some implementations.

FIG. 7 is a block diagram that illustrates an example of a computer system in which at least some operations described herein can be implemented.

The technologies described herein will become more apparent to those skilled in the art from studying the Detailed Description in conjunction with the drawings. Embodiments or implementations describing aspects of the invention are illustrated by way of example, and the same references can indicate similar elements. While the drawings depict various implementations for the purpose of illustration, those skilled in the art will recognize that alternative implementations can be employed without departing from the principles of the present technologies. Accordingly, while specific implementations are shown in the drawings, the technology is amenable to various modifications.

### DETAILED DESCRIPTION

Machine learning (ML) models used in the context of telecommunications services are rarely standardized and can often require different rates at which new training data samples are used to update model parameters to maintain certain thresholds of model accuracy. For example, a user equipment (UE) device of a telecommunications network system can have an embedded data analysis model (e.g., ML/AI model) that requires a minimum frequency at which the model parameters are retrained using new training data samples to maintain inferencing performance. As such, the network system can broadcast training data samples to the UE device for updating the data analysis model at a minimum required update frequency.

Updating embedded data analysis models (e.g., retraining and/or finetuning model parameters) locally on UE devices offer significant advantages over updating model parameters on a remote network server. In one aspect, updating models on a remote network server requires additional computational resources and processing complexity, as the server is responsible for generating updated model parameters (e.g., a resource intensive task) and subsequently transmitting the updated model parameters to the respective UE device. In contrast, updating models locally on the UE device simply requires the network to transmit a collected sample of training data to the UE device to be used by the UE device. Since network servers are often responsible for simultaneously communicating information between multiple UE devices within a coverage area, minimizing network-side processing tasks (e.g., only responsible for transmitting training samples) results in overall improved time efficiency (e.g., latency between service of UE devices) and reduced traffic to the network server.

Furthermore, configuring the network server to transmit data to UE devices for local model training allows for increased flexibility in propagating model updates to UE devices. As an illustrative example, the network server can be configured to transmit low-overhead delta values (e.g., backpropagation gradients) of model parameters to UE devices, such that the delta values are locally applied to update the model. In another example, the network server can be configured to transmit one or more data augmentation functions (e.g., instructions performed at the UE device) to the UE devices for generating new training data samples from modifications to existing local training data. Accordingly, establishing the network server as a lightweight model data source (e.g., training data and/or additional data types) and each UE device as the actual model update processor (e.g., performing resource intensive update tasks) will reduce significant resource consumption on server-side processes and improve performance efficiencies.

In another aspect, updating models locally at the UE device can provide enhanced privacy considerations regarding data handling and usage. As an illustrative example, in scenarios where updating a model requires additional user information captured at the UE device (e.g., user interaction information), updating models at the network server would require the UE device to submit potentially user sensitive information to the network server. As a result, the user sensitive information may be subjected to increased risk of exposure either during wireless communication or data handling within the network server. Thus, configuring the network server to submit training sample data to the UE device for local model updates enables limited exposure of potentially sensitive information. For these and additional reasons, there exists great motivation to implement computationally efficient methods to transmit model training data to respective UE devices for local updates.

A device-agnostic update method would result in transmitting training samples to a UE device at a uniform update frequency regardless of the dynamic minimum frequency at which a model needs to be updated to maintain sufficient performance. As a result, this method would frequently transmit excess training samples that produce marginal model performance benefits upon updating the model. As training advanced models requires increasingly large amounts of training data and computational power, the device-agnostic method can result in significant overhead data transfer costs (e.g., network traffic) that lack proportional improvements to model accuracy. Accordingly, there is a need for a system that can minimize overhead data transfer costs by optimizing frequencies at which new training data samples are broadcasted to UE devices for updating models while maintaining sufficient model performance.

To solve these problems, disclosed herein are systems and related methods for managing update groups of UE devices to enable efficient broadcasting of training data samples to respective UE devices for updating data analysis models. The disclosed system evaluates environmental parameters of the UE device and/or model parameters of the data analysis models to assign the UE device to an appropriate update group that reduces overhead data transfer from a network server to the respective UE device.

In some instances, the minimum required update frequency for the data analysis model of the UE device can vary significantly depending on immediate environmental parameters (e.g., device speed, altitude, location, and/or the like) of the UE device. For example, a data analysis model of a stationary UE device with constant environmental parameters can require less frequent updates to the model parameters to maintain model accuracy. In contrast, a data analysis model of a rapidly moving UE device (e.g., on a moving vehicle) can require more frequent updates to the model parameters as the environmental parameters shift frequently. Accordingly, the disclosed system can assign the UE device to one or more update groups each corresponding to an update frequency that satisfies the update requirements for a data analysis model of the UE device.

For each update group, the network system can assign a minimum required update frequency for broadcasting new training data samples to member UE devices (e.g., of the update group), resulting in a minimized overhead data transfer from the system to the member UE devices (e.g., reducing computational and memory resource consumption of both the system and the UE devices). For example, the network system can implement a repeating update loop that activates a dedicated update event for each update group at an activation rate based on the minimum required update frequency of the update group. In response to detecting an activated update event, the network system can broadcast new training samples to member UE deices of the update group corresponding to the update event.

In some implementations, the network system can update assignments of a UE device to update groups based on detected changes in environmental parameters of the UE device. For example, the system can receive an updated set of environmental parameters from the UE device to determine whether the current set of environmental parameters has shifted from a previous set of environmental parameters received in an earlier time. In response to determining a significant shift in the environmental parameters, the system can reassign the UE device to different update groups based on the updated set of environmental parameters. For example, the system can detect when a stationary UE device begins to move rapidly (e.g., on a moving vehicle) and subsequently reassign the UE device to a high frequency update group for data analysis models of the UE device.

Advantages of the disclosed technology include improved ability to manage overhead data transfers of training samples to UE devices at fine granularities, such as by identifying a minimum required update frequency for each data analysis model of a UE device. Additionally, the disclosed technology can assign multiple UE devices with models that have similar minimum required update frequencies into combined update groups. As a result, the disclosed technology can efficiently broadcast training data samples to member UE devices of a selected update group together while still minimizing the frequency at which training data samples are transferred to the member UE devices, resulting in reduced computational and memory resource costs. Furthermore, the disclosed technology can dynamically reassign a UE device to a new update group (e.g., with a different minimum update frequency) based on detected changes in environmental parameters of the UE device. As a result, the system can dynamically adjust the transfer rate of training data samples to UE devices based on the specific device environment and/or needs of the data analysis models. A person generally skilled in the art will appreciate that each advantage by themselves, or in combination, provides a significant reduction in unnecessary overhead data transfers from the system to UE devices.

For illustrative purposes, examples are described herein in the context of UE devices communicatively coupled to a telecommunications network system. However, a person skilled in the art will appreciate that the disclosed system can be applied in other contexts. For example, the disclosed system can be used to manage update groups for broadcasting training data samples to other types of wireless devices, such as vehicular navigation systems, network maintenance systems, and other wireless computing devices that leverage results from data analysis models (e.g., ML model).

The operation to minimize frequency of broadcasting training data samples to UE devices as disclosed herein causes a reduction in greenhouse gas emissions compared to conventional methods of transmitting uniform model updates that often include excess training samples. Every year, approximately 40 billion tons of CO₂ are emitted around the world. Power consumption by digital technologies including telecommunications networks and UE devices account for approximately 4% of this figure. Further, frequent unnecessary broadcast of large training data samples can exacerbate the causes of climate change. For example, the average U.S. power plant expends approximately 600 grams of carbon dioxide for every kWh generated. The implementations disclosed herein for minimizing frequency of training data broadcasting can mitigate climate change by reducing and/or preventing additional greenhouse gas emissions into the atmosphere. For example, reducing frequency of updates based on a change in UE device environment (e.g., or model requirements) as described herein reduces electrical power consumption by both the network system and the UE device. By reducing the frequency of transmitting data from the network server to the UE device, the disclosed systems reduce computationally heavy processes and can also provide increased battery efficiency to UE devices compared to traditional methods.

The description and associated drawings are illustrative examples and are not to be construed as limiting. This disclosure provides certain details for a thorough understanding and enabling description of these examples. One skilled in the relevant technology will understand, however, that the invention can be practiced without many of these details. Likewise, one skilled in the relevant technology will understand that the invention can include well-known structures or features that are not shown or described in detail, to avoid unnecessarily obscuring the descriptions of examples.

### Wireless Communications System

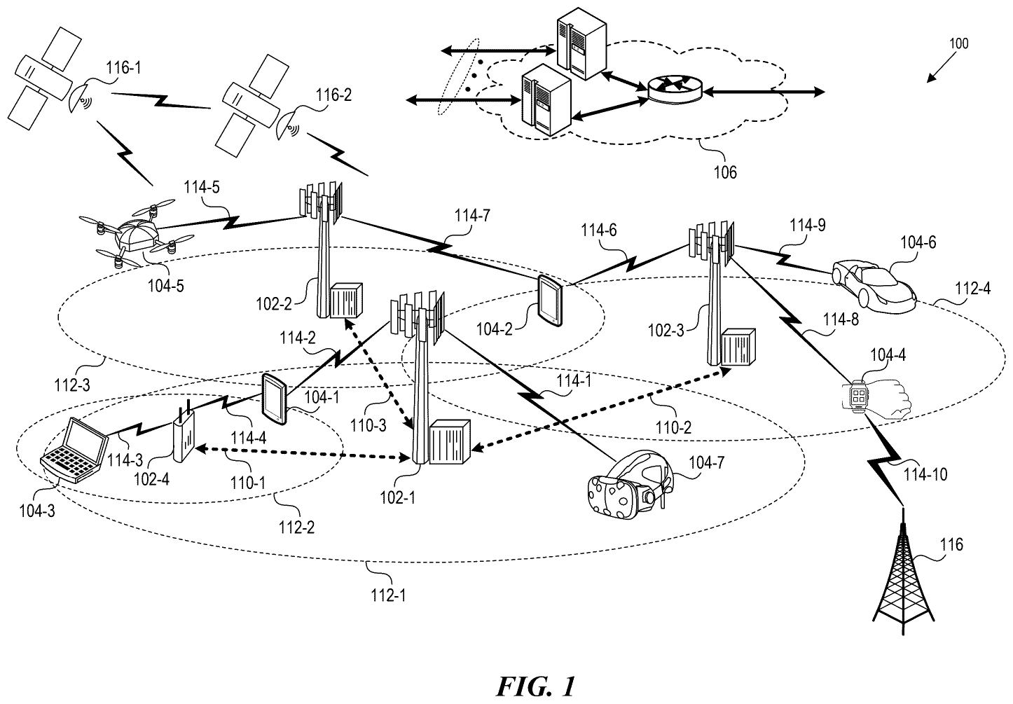

FIG. 1 is a block diagram that illustrates a wireless telecommunication network 100 (“network 100”) in which aspects of the disclosed technology are incorporated. The network 100 includes base stations 102-1 through 102-4 (also referred to individually as “base station 102” or collectively as “base stations 102”). A base station is a type of network access node (NAN) that can also be referred to as a cell site, a base transceiver station, or a radio base station. The network 100 can include any combination of NANs including an access point, radio transceiver, gNodeB (gNB), NodeB, eNodeB (eNB), Home NodeB or Home eNodeB, or the like. In addition to being a wireless wide area network (WWAN) base station, a NAN can be a wireless local area network (WLAN) access point, such as an Institute of Electrical and Electronics Engineers (IEEE) 802.11 access point.

The NANs of a network 100 formed by the network 100 also include wireless devices 104-1 through 104-7 (referred to individually as “wireless device 104” or collectively as “wireless devices 104”) and a core network 106. The wireless devices 104 can correspond to or include network 100 entities capable of communication using various connectivity standards. For example, a 5G communication channel can use millimeter wave (mmW) access frequencies of 28 GHz or more. In some implementations, the wireless device 104 can operatively couple to a base station 102 over a long-term evolution/long-term evolution-advanced (LTE/LTE-A) communication channel, which is referred to as a 4G communication channel.

The core network 106 provides, manages, and controls security services, user authentication, access authorization, tracking, internet protocol (IP) connectivity, and other access, routing, or mobility functions. The base stations 102 interface with the core network 106 through a first set of backhaul links (e.g., S1 interfaces) and can perform radio configuration and scheduling for communication with the wireless devices 104 or can operate under the control of a base station controller (not shown). In some examples, the base stations 102 can communicate with each other, either directly or indirectly (e.g., through the core network 106), over a second set of backhaul links 110-1 through 110-3 (e.g., X1 interfaces), which can be wired or wireless communication links.

The base stations 102 can wirelessly communicate with the wireless devices 104 via one or more base station antennas. The cell sites can provide communication coverage for geographic coverage areas 112-1 through 112-4 (also referred to individually as “coverage area 112” or collectively as “coverage areas 112”). The coverage area 112 for a base station 102 can be divided into sectors making up only a portion of the coverage area (not shown). The network 100 can include base stations of different types (e.g., macro and/or small cell base stations). In some implementations, there can be overlapping coverage areas 112 for different service environments (e.g., Internet of Things (IoT), mobile broadband (MBB), vehicle-to-everything (V2X), machine-to-machine (M2M), machine-to-everything (M2X), ultra-reliable low-latency communication (URLLC), machine-type communication (MTC), etc.).

The network 100 can include a 5G network 100 and/or an LTE/LTE-A or other network. In an LTE/LTE-A network, the term “eNBs” is used to describe the base stations 102, and in 5G new radio (NR) networks, the term “gNBs” is used to describe the base stations 102 that can include mmW communications. The network 100 can thus form a heterogeneous network 100 in which different types of base stations provide coverage for various geographic regions. For example, each base station 102 can provide communication coverage for a macro cell, a small cell, and/or other types of cells. As used herein, the term “cell” can relate to a base station, a carrier or component carrier associated with the base station, or a coverage area (e.g., sector) of a carrier or base station, depending on context.

A macro cell generally covers a relatively large geographic area (e.g., several kilometers in radius) and can allow access by wireless devices that have service subscriptions with a wireless network 100 service provider. As indicated earlier, a small cell is a lower-powered base station, as compared to a macro cell, and can operate in the same or different (e.g., licensed, unlicensed) frequency bands as macro cells. Examples of small cells include pico cells, femto cells, and micro cells. In general, a pico cell can cover a relatively smaller geographic area and can allow unrestricted access by wireless devices that have service subscriptions with the network 100 provider. A femto cell covers a relatively smaller geographic area (e.g., a home) and can provide restricted access by wireless devices having an association with the femto unit (e.g., wireless devices in a closed subscriber group (CSG), wireless devices for users in the home). A base station can support one or multiple (e.g., two, three, four, and the like) cells (e.g., component carriers). All fixed transceivers noted herein that can provide access to the network 100 are NANs, including small cells.

The communication networks that accommodate various disclosed examples can be packet-based networks that operate according to a layered protocol stack. In the user plane, communications at the bearer or Packet Data Convergence Protocol (PDCP) layer can be IP-based. A Radio Link Control (RLC) layer then performs packet segmentation and reassembly to communicate over logical channels. A Medium Access Control (MAC) layer can perform priority handling and multiplexing of logical channels into transport channels. The MAC layer can also use Hybrid ARQ (HARQ) to provide retransmission at the MAC layer, to improve link efficiency. In the control plane, the Radio Resource Control (RRC) protocol layer provides establishment, configuration, and maintenance of an RRC connection between a wireless device 104 and the base stations 102 or core network 106 supporting radio bearers for the user plane data. At the Physical (PHY) layer, the transport channels are mapped to physical channels.

Wireless devices can be integrated with or embedded in other devices. As illustrated, the wireless devices 104 are distributed throughout the network 100, where each wireless device 104 can be stationary or mobile. For example, wireless devices can include handheld mobile devices 104-1 and 104-2 (e.g., smartphones, portable hotspots, tablets, etc.); laptops 104-3; wearables 104-4; drones 104-5; vehicles with wireless connectivity 104-6; head-mounted displays with wireless augmented reality/virtual reality (AR/VR) connectivity 104-7; portable gaming consoles; wireless routers, gateways, modems, and other fixed-wireless access devices; wirelessly connected sensors that provide data to a remote server over a network; IoT devices such as wirelessly connected smart home appliances; etc.

A wireless device (e.g., wireless devices 104) can be referred to as a user equipment (UE), a customer premises equipment (CPE), a mobile station, a subscriber station, a mobile unit, a subscriber unit, a wireless unit, a remote unit, a handheld mobile device, a remote device, a mobile subscriber station, a terminal equipment, an access terminal, a mobile terminal, a wireless terminal, a remote terminal, a handset, a mobile client, a client, or the like.

A wireless device can communicate with various types of base stations and network 100 equipment at the edge of a network 100 including macro eNBs/gNBs, small cell eNBs/gNBs, relay base stations, and the like. A wireless device can also communicate with other wireless devices either within or outside the same coverage area of a base station via device-to-device (D2D) communications.

The communication links 114-1 through 114-9 (also referred to individually as “communication link 114” or collectively as “communication links 114”) shown in network 100 include uplink (UL) transmissions from a wireless device 104 to a base station 102 and/or downlink (DL) transmissions from a base station 102 to a wireless device 104. The downlink transmissions can also be called forward link transmissions while the uplink transmissions can also be called reverse link transmissions. Each communication link 114 includes one or more carriers, where each carrier can be a signal composed of multiple sub-carriers (e.g., waveform signals of different frequencies) modulated according to the various radio technologies. Each modulated signal can be sent on a different sub-carrier and carry control information (e.g., reference signals, control channels), overhead information, user data, etc. The communication links 114 can transmit bidirectional communications using frequency division duplex (FDD) (e.g., using paired spectrum resources) or time division duplex (TDD) operation (e.g., using unpaired spectrum resources). In some implementations, the communication links 114 include LTE and/or mmW communication links.

In some implementations of the network 100, the base stations 102 and/or the wireless devices 104 include multiple antennas for employing antenna diversity schemes to improve communication quality and reliability between base stations 102 and wireless devices 104. Additionally or alternatively, the base stations 102 and/or the wireless devices 104 can employ multiple-input, multiple-output (MIMO) techniques that can take advantage of multi-path environments to transmit multiple spatial layers carrying the same or different coded data.

In some examples, the network 100 implements 6G technologies including increased densification or diversification of network nodes. The network 100 can enable terrestrial and non-terrestrial transmissions. In this context, a Non-Terrestrial Network (NTN) is enabled by one or more satellites, such as satellites 116-1 and 116-2, to deliver services anywhere and anytime and provide coverage in areas that are unreachable by any conventional Terrestrial Network (TN). A 6G implementation of the network 100 can support terahertz (THz) communications. This can support wireless applications that demand ultrahigh quality of service (QOS) requirements and multi-terabits-per-second data transmission in the era of 6G and beyond, such as terabit-per-second backhaul systems, ultra-high-definition content streaming among mobile devices, AR/VR, and wireless high-bandwidth secure communications. In another example of 6G, the network 100 can implement a converged Radio Access Network (RAN) and Core architecture to achieve Control and User Plane Separation (CUPS) and achieve extremely low user plane latency. In yet another example of 6G, the network 100 can implement a converged Wi-Fi and Core architecture to increase and improve indoor coverage.

### Device Grouping System

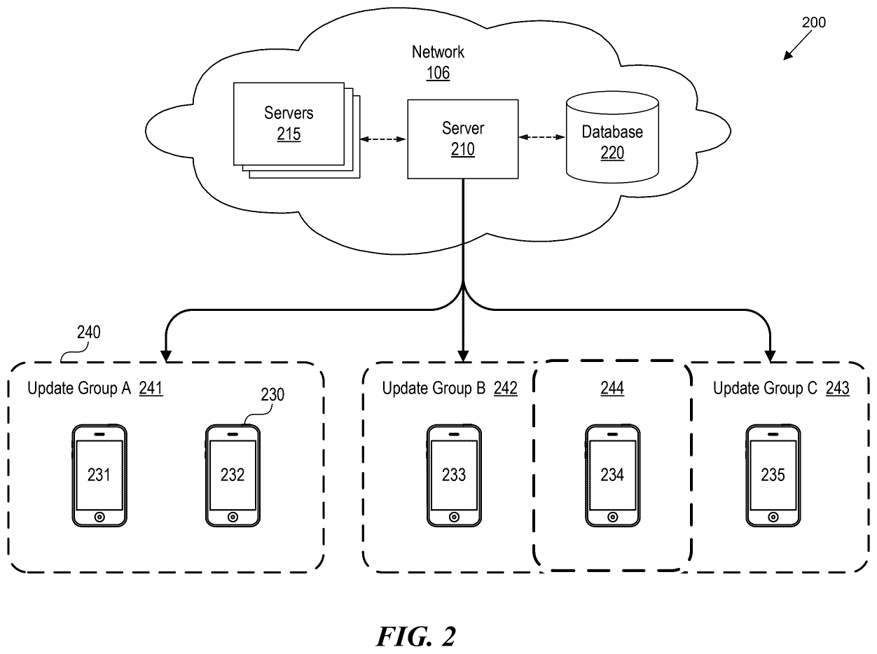

FIG. 2 is a block diagram that illustrates components of a device grouping system 200 in some implementations. The system 200 includes a network server 210, a database 220, a set of UE devices 230, and a set of update groups 240 which are discussed in further detail below. All or portions of system 200 can be provided, for example, by a telecommunications service that provides all or portions of the system 200 using one or more components of the network 100.

UE devices 230 (e.g., devices 231, 232, 233, 234, and 235) are devices configured to communicate over a telecommunications network 100 and can include, for example, wireless devices 104 as described with respect to FIG. 1. Each of the UE devices 230 can use a data analysis model (e.g., a local model) that is based on a machine learning architecture (e.g., multi-layer perceptron) to perform various tasks for operating on the telecommunications network. In at least some implementations, the data analysis model is provided by a network server 210, which can perform initial training of the model.

In various examples, a data analysis model can be used by the UE device 230 to control and/or monitor performance of the UE device 230 as it operates on the telecommunications network 100. For example, the network server can provide a data analysis model to a UE device 230 for computing channel state information (CSI) of the UE device 230. In other examples, the network server 210 can provide a data analysis model to a set of UE devices 230 for controlling performance of the UE devices 230. Furthermore, the network server 210 can provide a plurality of data analysis models to a select UE device 230, such that each data analysis model in the plurality of data analysis models control several functions and/or monitor performances of the select UE device 230.

The data analysis model may need or benefit from periodic updates or retraining, for example as model drift occurs or as new training data is received. Accordingly, the UE device 230 can be configured to iteratively adjust a set of internal parameters (e.g., model parameters) of the data analysis model (e.g., training the data analysis model) based on a set of training data samples that are representative of expected input and output parameters of the data analysis model. The set of training data samples can include samples collected by the network server 210 based on observations of the input and output parameters. For example, the network server 210 can transmit a set of new training data samples (e.g., labeled training samples) to a UE device 230 for updating a local data analysis model. In some implementations, the data analysis model is updated based on a set of model maintenance parameters, such as a hardware specification based on a UE device 230, a software requirement for an application hosted on the UE device 230, a data format associated with the particular data analysis model, or a set of parameters corresponding to output data of the data analysis model.

The network server 210 communicates with the UE devices 230 to provide data analysis models for use by the UE devices and to supply data to maintain these models. To reduce overhead data transfer of model training samples to UE devices 230, a network server 210 can employ systems and methods described herein to assign the UE devices 230 to select update groups with corresponding update frequencies. For example, a first update group can have a high update frequency, such that UE devices assigned to the first update group receive relatively frequent updates to model training samples. At the same time, a second update group can have a lower update frequency, such that UE devices assigned to the second update group receive less frequent updates to the model training samples. Devices can be assigned to the second update group because, for example, they are operating in an environment in which the data analysis model is more likely to remain sufficiently accurate without retraining, an environment in which inaccurate predictions caused by drift of the data analysis model are less likely to significantly impact the performance of the UE devices, or an environment in which the UE devices only infrequently use the data analysis model to generate predictions. By assigning these devices that do not need the data analysis model to be updated as frequently as do other devices to a lower-frequency update group, implementations described herein result in transmitting less data over the telecommunications network. The systems and/or methods can be implemented with a combination of software (e.g., executable instructions or computer code) and hardware (e.g., one or more memories and one or more processors). Accordingly, as used herein, in some examples the network server 210 represents a computing device having one or more processors that are at least temporarily configured and/or programmed by executable instructions carried in one or more memories to perform one or more of the functions described herein.

In some embodiments, the network server can be a single instance of a plurality of network servers 215 hosted on the network 106. For example, the network server 210 can be a dedicated computing device within the plurality of network servers 215 for implementing one or more functionalities of the grouping system 200 described herein. Although functions and methods of the grouping system 200 are described herein with respect to a single network server 210, the grouping system 200 can configure a plurality of network servers 215 to collectively perform the one or more functions described herein, such that each network server 210 can perform a partial function of the grouping system 200 that works in tandem with other network servers 210 in the plurality of network servers 215.

In some embodiments, the network server 210 can be communicatively coupled to a database 220 hosted on the network 106. The network server 210 can be coupled to a database 220 that stores data analysis models and model training samples for use by UE devices 230 that are communicatively coupled to the network 106 via a telecommunications service. For example, the network server 210 can retrieve training data samples from the database 220 to update data analysis models for computing channel state information (CSI) and/or multi-beamforming at the UE devices 230. In additional or alternative embodiments, the network server 210 an transmit a copy of a data analysis model from the database 220 to a UE device 230 for local use within the UE device 230.

In some embodiments, the network server 210 can receive a set of device environment parameters from a UE device 230. The set of device environment parameters can include a location of the UE device 230, a mobility state (e.g., stationary, slow movement, rapid movement) of the UE device 230, a communication quality measure between the network system 210 and the UE device 230, a measure of network traffic with respect to the network system 210, or any combination thereof. In additional, or alternative embodiments, the network server 210 can receive a set of device environment parameters from the UE device 230 that are actively monitored at the UE device 230. For example, the network server 210 can receive detected changes in the set of device environment parameters from a select UE device 230.

In some embodiments, the network server 210 can assign a UE device 230 to an update group 240 based on a set of device environment parameters of the UE device 230. For example, the network server 210 can assign the UE device 230 to an appropriate update group 240 based on a current set of device environment parameters that was received from the UE device 230 at a particular moment in time. In further embodiments, the network server 210 can assign the UE device 230 to an update group 240 that includes other UE devices 230 with similar device environment parameters. In additional, or alternative embodiments, the network server 210 can assign a select UE device 230 from a plurality of UE devices 230 to a selected update group from a plurality of update groups.

As shown in FIG. 2, the network server 210 can assign a first UE device 231 to a first update group 241 (e.g., “Update Group A”) based on a first set of device environment parameters corresponding to the first UE device 231. Likewise, the network server 210 can assign a second UE device 232 to the same first update group 241 based on a second set of device environment parameters corresponding to the second UE device 232, such that both the first and the second UE devices 231, 232 are member devices of the first update group 241. Similarly, the network server 210 can assign a third UE device 233 to a second update group 242 (e.g., “Update Group B”) based on a third set of device environment parameters corresponding to the third UE device 233 and assign a fourth UE device 235 to a third update group 243 (e.g., “Update Group C”) based on a fourth set of device environment parameters corresponding to the fourth UE device 235. In some embodiments, the network server 210 can assign a select UE device 230 to a plurality of update groups 240. For example, the network server 210 can assign a fifth UE device 234 to both the second update group 242 and the third update group 243 based at least in part a fifth set of device environment parameters corresponding to the fifth UE device 234.

In some embodiments, the network server 210 can assign a unique update frequency to an update group 240 comprising one or more member UE devices 230. For example, the network server 210 can receive a set of model maintenance parameters corresponding to each member UE device 230 assigned to the update group 240. Based on the set of model maintenance parameters of the UE devices 230, the network server 210 can determine an update frequency for the update group 240, where the update frequency corresponds to an activation rate of periodic update events, where each update event causes the network server 210 to broadcast update data samples to member UE devices 230 of update group 240 for training data analysis models. In additional, or alternative embodiments, the network server 210 can select an update frequency for an update group 240 from a predetermined set of available update frequencies.

In some embodiments, the network server 210 can include a minimum viable frequency predictor for determining minimum viable update frequencies for update groups 240. For example, the network server 210 can use the minimum viable frequency predictor to determine a minimum viable update frequency for an update group 240 corresponding to a minimum required activation rate of periodic update events for broadcasting update data samples to member UE devices 230 for updating one or more data analysis models. As such, the minimum viable update frequency is representative of a minimum update frequency necessary for adjusting data analysis models used by member UE devices 240 to maintain adequate model performance and/or inference accuracy.

In some embodiments, the network server 210 can assign multiple UE devices 230 that use a data analysis model into different update groups 240 each with a different assigned minimum viable update frequency. For example, the network server 210 can assign a first UE device and a second UE device that use the same data analysis model to a first update group and a second update group respectively, where the first and the second update groups are assigned different minimum viable update frequencies. As such, the network server 210 can determine one or more unique minimum viable update frequencies for updating a single data analysis model based on UE devices 230 that are assigned to different update groups 240.

In additional, or alternative embodiments, the network server 210 can use the minimum viable frequency predictor to determine the minimum viable frequency for the update group 240 based on a set of device environment parameters of member UE devices 230, a set of model maintenance parameters corresponding to data analysis models used by the member UE devices 230, or a combination thereof. For example, the network server 210 can use the minimum viable frequency predictor to determine a low minimum viable frequency for a first update group 240 comprising a first set of member UE devices 230 corresponding to a slow mobility state (e.g., stationary, walking) and a high minimum viable frequency for a second update group 240 comprising a second set of member UE devices 230 corresponding to a fast mobility state (e.g., running, driving). In another example, the network server 210 can determine a high minimum viable frequency for an update group 240 that comprises a set of member UE devices 230 using a high-performance data analysis model (e.g., inference models for CSI and/or modulation encoding rates) that requires frequent adjustments to internal model parameters. In some embodiments, the network server 210 can assign a candidate update frequency to the update group 240 that is selected from a predetermined set of available update frequencies such that the candidate update frequency is closest (e.g., frequency value) to a determined minimum viable frequency for the update group 240 using the minimum frequency predictor. In further embodiments, the network server 210 can use a minimum viable frequency predictor that is based on a machine learning model architecture to inference minimum viable frequencies for update groups 240.

In some embodiments, the network server 210 can assign a UE device 230 to an update group 240 based on a set of model maintenance parameters of a data analysis model used by the UE device 230. For example, the network server 210 can receive a set of model maintenance parameters for a data analysis model from a UE device 230 that uses the data analysis model for performance. Using the received set of model maintenance parameters, the network server 210 can determine an update frequency (e.g., minimum viable update frequency) for the data analysis model used by the UE device 230. Furthermore, the network server 210 can assign the UE device 230 to an update group 240 with an assigned minimum viable update frequency that is closest (e.g., within a specified frequency threshold range) to the determined update frequency for the data analysis model used by the UE device 230.

In some embodiments, the network server 210 can broadcast update data samples to member UE devices 230 of an update group 240 in response to a detected update event. The update event can be associated with an event trigger mechanism (e.g., at the network server) to initiate an update of one or more update groups after a specified time duration has passed since a previous update event. For example, the network server 210 can receive a periodic update event (e.g., after a constant time duration) corresponding to an assigned update frequency for an update group 240. In response to the periodic update event, the network server 210 can selectively broadcast a set of update data samples to member UE devices 230 of the update group 240 for updating one or more data analysis models used by the member UE devices 230. As shown in FIG. 2, the network server 210 can receive a periodic update event corresponding to an assigned update frequency for an update group 241 comprising two member UE devices 231, 232. In response to the periodic update event, the network server 210 can selectively broadcast a set of update data samples to each member UE device 231, 232 of the update group 241 for updating the data analysis models used by the member UE devices 231, 232. In additional or alternative embodiments, the update event can be triggered at the network server based on a notification received from a connected UE device, where the notification indicates that an embedded model in the UE device has reached a performance level below an expected threshold.

In some embodiments, the network server 210 can reassign a UE device 230 to a different update group 240 based on detected changes to a set of device environment parameters of the UE device 230. For example, the network server 210 can receive a first set of device environment parameters for a UE device 230 at a first timestamp and a second set of device environment parameters for the UE device 230 at a second timestamp. Using the first and the second set of device environment parameters, the network server 210 can detect a significant update (e.g., measured differences) between the first and the second sets of device environment parameters of the UE device 230. As an example, the network server 210 can detect significant updates between the first and the second sets of device environment parameters including changes to network-based location measurements (e.g., relative distance between UE device and network station), ICAS integrated communication sensor data (e.g., angle of arrival, doppler information, location data via radar), levels of network traffic (e.g., congestion of network traffic between UE devices and a base station), or a combination thereof. In response to detecting the significant update, the network server 210 can assign the UE device 230 to a different update group 240 from a plurality of available update groups based on the second set of device environment parameters. In additional, or alternative embodiments, the network server 210 can assign the UE device 230 to a new update group 240 (e.g., creating and adding new update group to plurality of update groups) upon determining that no existing update group 240 from the plurality of available update groups are sufficient (e.g., comparison to predetermined thresholds) for the UE device 230 based on the second set of device environment parameters.

In some embodiments, the network server 210 can dynamically combine multiple update groups 240 based on each assigned update frequency. For example, the network server 210 can identify a first update group from a plurality of update groups, such that the first update group is assigned a first update frequency, and a second update group from the plurality of update groups, such that the second update group is assigned a second update frequency different from the first update frequency. Further, the network server 210 can determine whether the difference between values of the first and the second update frequencies are within a similarity threshold (e.g., frequency range of similar frequency values). In response to determining that the measured difference between the first and the second update frequencies is within the similarity threshold, the network server 210 can determine a third update frequency based on the first and the second update frequencies. For example, the network server 210 can determine the third update frequency as a midpoint frequency value between the first and the second update frequencies. Furthermore, the network server 210 can reassign member UE devices 240 of both the first and the second update groups to a third update group from the plurality of update groups such that the third update group is assigned the third update frequency.

### Electronic Device

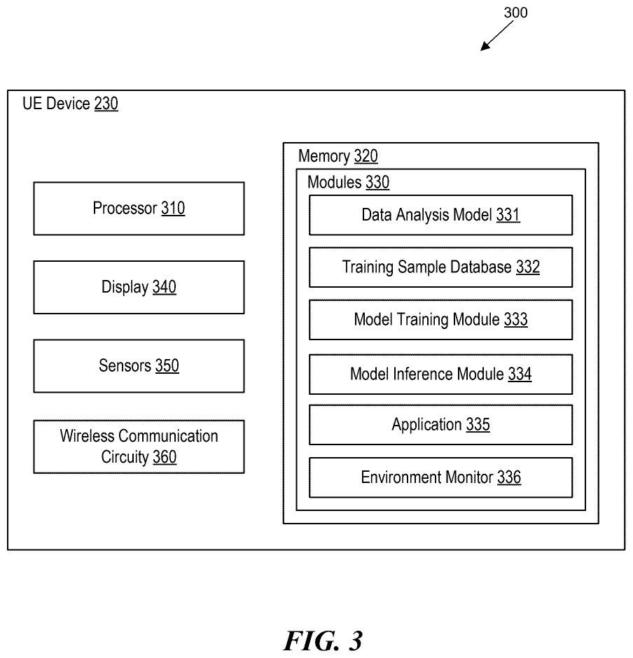

FIG. 3 is a block diagram that illustrates components of a user equipment device 230 in some implementations. The components shown in FIG. 3 are merely illustrative and well-known components are omitted for brevity. As shown, the UE device 230 includes a processor 310, a memory 320, a display 340, and sensors 350. The UE device 230 can also include wireless communication circuitry 360 designed to establish wireless communication channels with other computing devices. The processor 310 can have generic characteristics similar to general-purpose processors, or the processor 310 can be an application-specific integrated circuit (ASIC) that provides arithmetic and control functions to the UE device 230. While not shown, the processor 310 can include a dedicated cache memory. The processor 310 can be coupled to all components of the UE device 230, either directly or indirectly, for data communication.

The memory 320 can be comprised of any suitable type of storage device including, for example, a static random-access memory (SRAM), dynamic random-access memory (DRAM), electrically erasable programmable read-only memory (EEPROM), flash memory, latches, and/or registers. In addition to storing instructions which can be executed by the processor 310, the memory 320 can also store data generated by the processor 310 (e.g., when executing the modules of an optimization platform). The memory 320 is merely an abstract representation of a storage environment. Hence, in some embodiments, the memory 320 is comprised of one or more actual memory chips or modules.

An example of the display 340 includes a touch-enabled display or a non-touch-enabled display, in which case the UE device 230 likely also includes (or is connected to) an input device such as a keyboard. An example of the wireless communication circuitry 360 forms and/or communicate with a network for data transmission among computing devices, such as personal computers, mobile phones, and computer servers. The wireless communication circuitry 360 can be used for communicating with these computing devices or for connecting to a higher-level network (e.g., a LAN) or the Internet. Examples of wireless communication circuitry 3600 include Bluetooth, Z-Wave, ZigBee, and the like. In some embodiments, the connection established by the wireless communication circuitry 360 can be bootstrapped by a near field communication (NFC) connection.

The sensors 350 can comprise any suitable type of hardware and/or software sensors within the UE device 230 that sense parameters of the UE device 230 or an environment of the UE device 230. The sensors 350 can include, for example, one or more of an internal device accelerometer, a satellite-based radio navigation system (e.g., GPS), a digital power source monitor (e.g., battery life sensor), or a communication signal strength indicator. In addition to determining various internal and external conditions of the UE device 230, the sensors 350 can also be used to generate time-sensitive (e.g., real-time) records of an operation environment for the UE device 230. The sensors 350 are merely an abstract representation of a set of built-in measurement tools that detects an environment state within and/or outside of the UE device 230.

As shown in FIG. 3, the memory 320 can include several modules 330 for both storing instructions to be executed by processor 310 and storing data generated by the processor 310. For example, the memory 320 can store a local data analysis model 331 that can be used by the processor 310 to monitor and/or control performance of the UE device 230 (e.g., inferencing CSI information). The memory 320 can also include a dedicated training sample database 332, a model training module 333, and a model inference module 334 for maintaining, updating, and applying the local data analysis model 331. As an example, the processor 310 can update the local data analysis model 331 using the model training module 333 by incrementally train (e.g., adjust internal model parameters) the local data analysis model 331 based on new training sample data accessed from the training sample database 332. In some embodiments, the training sample database 332 can serve as a temporary storage module for holding unused training data samples until the next model training session. As such, the processor 310 can remove training data samples stored in the training sample database 332 after completing a model training session. Furthermore, the processor 310 can receive a new set of training data samples from a network server 210 by using the wireless communication circuitry 360 to connect the UE device 230 to the network server 210 via telecommunication service.

In additional, or alternative embodiments, the processor 310 can use the model inference module 334 to generate inference results from the local data analysis model 331 for augmenting an application 332 that is hosted the UE device 230 and visualized on the display 340. In further embodiments, the memory 320 can include an environment monitor 336 module for detecting significant device environment parameters (e.g., external and/or internal device environment) captured by sensors 350 embedded within the UE device 230. For example, the processor 310 can use the environment monitor 336 to store time-sensitive (e.g., real-time) records of device environment parameters from the sensors 350 into the memory 320. Furthermore, the processor 310 can communicate the stored time-sensitive records of device environment parameters to the network server 210 using the wireless communication circuitry 360.

### Network Server

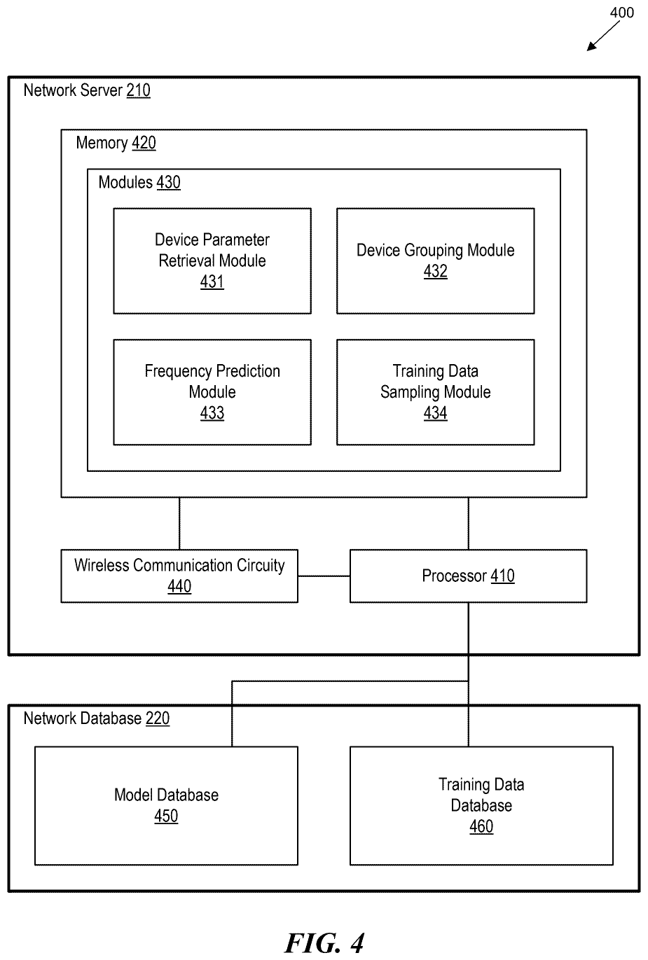

FIG. 4 is a block diagram that illustrates components of a network server 210 in some implementations. The components shown in FIG. 4 are merely illustrative and well-known components are omitted for brevity. As shown, the network server 210 includes a processor 410, a memory 420, and a wireless communication circuitry 440. The network server 210 can use the wireless communication circuitry 440 to establish wireless communication channels with other computing devices. The processor 410 can have generic characteristics similar to general-purpose processors, or the processor 410 can be an application-specific integrated circuit (ASIC) that provides arithmetic and control functions to the network server 210. While not shown, the processor 410 can include a dedicated cache memory. The processor 410 can be coupled to all components of the network server 210, either directly or indirectly, for data communication. Further, the processor 410 of the network server 210 can be communicatively coupled to a network database 220 that is hosted alongside the network server 210 on the telecommunications network 106. As shown, the network database 220 can include a model database 450 and a training data database 460.

The memory 420 can be comprised of any suitable type of storage device including, for example, a static random-access memory (SRAM), dynamic random-access memory (DRAM), electrically erasable programmable read-only memory (EEPROM), flash memory, latches, and/or registers. In addition to storing instructions which can be executed by the processor 410, the memory 420 can also store data generated by the processor 410 (e.g., when executing the modules of an optimization platform). In additional, or alternative embodiments, the processor 410 can store temporary information onto the memory 420 and store long-term data onto the network database 220. The memory 420 is merely an abstract representation of a storage environment. Hence, in some embodiments, the memory 420 is comprised of one or more actual memory chips or modules.

As shown in FIG. 4, the modules 430 of the memory 420 can include a device parameter retrieval module 431, a device grouping module 432, a frequency prediction module 433, and a training data sampling module 434. Other implementations of the network server 210 include additional, fewer, or different modules, or distribute functionality differently between the modules. As used herein, the term “module” refers broadly to software components, firmware components, and/or hardware components. Accordingly, the modules 431, 432, 433, 434 could each be comprised of software, firmware, and/or hardware components implemented in, or accessible to, the network server 210.

The device parameter retrieval module 431 monitors device parameters of UE devices 230 that are connected to the network server 210 via telecommunications network. For example, the device parameter retrieval module 431 can use the wireless communication circuitry 440 to receive a set of device environment parameters from a UE device 230 in real-time or at periodic intervals. As such, the device parameter retrieval module 431 can record the set of device environment parameters communicated by the UE device 230 into the memory 420. In some embodiments, the memory 420 serves as an efficient temporary storage for a latest set of device environment parameters for a UE device 230 connected to the network server 210. For example, the device parameter retrieval module 431 can replace an existing recorded set of device environment parameters for a UE device 230 on the memory 420 with a new set of device environment parameters received from the UE device 230 at a different point in time. In response to receiving a new set of device environment parameters for a UE device 230, the device parameter retrieval module 431 can also compare the new set of device environment parameters to an existing recorded set of device environment parameters for the UE device 230 to determine whether a significant shift (e.g., changes in measured parameters) occurred between the recorded and new sets of device environment parameters.

The device grouping module 432 assigns UE devices 230 to select update groups 240 from a plurality of update groups stored on the network database 220. For example, the device grouping module 432 can access a set of device environment parameters for a UE device 230 from the memory 420 (e.g., recorded by device parameter retrieval module 431) to identify a candidate update group 240 for the UE device 230. In additional, or alternative embodiments, the device grouping module 432 can identify the candidate update group 240 for the UE device 230 based on a data analysis model used by the UE device 230. For example, the device grouping module 432 can access a set of model maintenance parameters for the data analysis model (e.g., from the model database 450) used by the UE device 230 to identify the candidate update group 240 for the UE device 230.

In some embodiments, the device grouping module 432 can reassign a UE device 230 to a different update group 240 based on detected changes in a set of device environment parameters for a UE device 230. For example, the device grouping module 432 can reassign a UE device 230 from a first update group to a second update group based on a significant shift in one or more parameters of the set of device environment parameters, as determined by the device parameter retrieval module 431. In further embodiments, the device grouping module 432 can store a mapping information (e.g., a set of links, a graph, and/or the like) between available update groups 240 and assigned UE devices 230 on the network database 220.

The frequency prediction module 433 can determine an update frequency for each update group 230 in a plurality of available update groups stored on the network database 220. For example, the frequency prediction module 433 can access an update frequency predictor model from the model database 450 to estimate an update frequency for a select update group. In particular, the frequency prediction module 433 can use a set of device environment parameters for a member UE device 230 and/or a set of model maintenance parameters for a data analysis model used by the member UE device 230 to generate the estimated update frequency.

In some embodiments, the frequency prediction module 433 can estimate a minimum viable frequency for updating a data analysis model used by a UE device 230. As such, the device grouping module 432 can compare the estimated minimum viable frequency to update frequencies assigned to each update group 240 in the plurality of available update groups to assign the UE device 230 to a candidate update group 240 with an assigned update frequency that is closest to the estimated minimum viable frequency. In additional, or alternative embodiments, the frequency prediction module 433 can generate a similarity frequency range for an update group 240 such that the device grouping module 432 can assign UE devices 230 that use data analysis models with estimated minimum viable frequencies within the similarity frequency range to the update group 240.

The training data sampling module 434 can retrieve a set of training data samples for updating a data analysis model used by a UE device 230. As an example, the training data sampling module 434 can retrieve a recorded set of device environment parameters for the UE device 230 from the memory 420 (e.g., or from the network database 220) and a copy set of model maintenance parameters (e.g., from a template model) for the data analysis model used by the UE device 230 from the model database 450. Using the set of device environment parameters and the set of model maintenance parameters, the training data sampling module 434 can access the training data database 460 to generate a set of training data samples to be communicated (e.g., via the wireless communication circuitry 440) to the UE device 230 for updating the data analysis model. In particular, the training data sampling module 434 can generate a customized set of training data samples that are intended for a specified model architecture (e.g., model input and/or output requirements, data handling types, etc.) and/or a specified model update operation (e.g., retraining, embedding, finetuning, etc.). In some embodiments, the training data database 460 can include at least one set of training data samples for completing at least one full model training session for each data analysis model stored in the model database 450. In additional or alternative embodiments, the training data database 460 can store training data samples sourced from recorded connectivity information by a network server during communication with covered UE devices, server modified data of UE device transmitted information (e.g., user data, device environment information, etc.), and/or imported communications data from external systems (e.g., historical connectivity data for UE devices).

### Selectively Updating Model Parameters in a Telecommunications Network

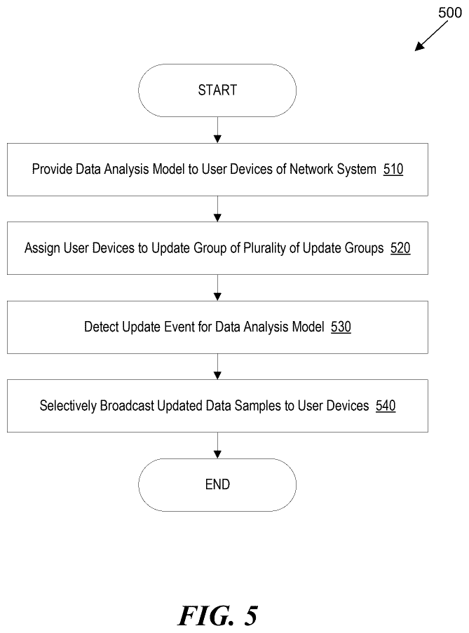

FIG. 5 is a flow diagram that illustrates a process to configure a network system in some implementations. The process 500 can be performed by a system (e.g., a network system) configured to minimize overhead data transfer of model training samples to UE devices of a telecommunications network. In one example, the network system includes at least one hardware processor and at least one non-transitory memory storing instructions, which, when executed by the at least one hardware processor, cause the network system to perform the process 500. In another example, the network system a non-transitory, computer-readable storage medium comprising instructions recorded thereon, which the instructions when executed by at least one data processor of a network system, cause the network system to perform the process 500.

At 510, the network system can provide a data analysis model to multiple user devices that are communicatively coupled to the network system via a telecommunications network. For example, the network system can provide the data analysis model to the multiple user devices such that the data analysis model is usable by the multiple user devices to control performance of the multiple user devices on the telecommunications network. In some embodiments, the data analysis model can include a model for computing channel state information (CSI), a model for performing beamforming, or a model based on a machine learning architecture.

At 520, the network system can assign each of the multiple user devices to a selected update group of a plurality of update groups, such that a respective user device is assigned to a corresponding selected update group based on a set of device environment parameters of the respective user device. Further, the network system can detect an update in the set of device environment parameters of the respective user device and assign the respective user device to a different update group from the plurality of update groups in response to the detected update to the updated set of device environment parameters. In some embodiments, the network system can generate a new update group within the plurality of update groups in response to a failed search of a valid update group for the respective device, such that the respective user device is added to the new update group. In additional, or alternative embodiments, the set of device environment parameters can include a location of the user device, a change in the location of the user device, a communication quality measure between the user device and the network system, or a measure of network traffic at the network system.

In other embodiments, the network system can provide a second data analysis model to a selected user device of the multiple user devices communicatively coupled to the network system via a telecommunications network such that the second data analysis model is usable by the selected user device to control performance of the selected user device on the telecommunications network. Further, the network system can assign the selected user device to a second selected update group of the plurality of update groups, such that the selected user device is assigned to the second selected update group based on a second set of device environment parameters and the second selected update group is different from the selected update group already assigned to the selected user device.

In some embodiments, the network system can iteratively, for each update group of the plurality of update groups, receive a set of model maintenance parameters for member user devices of the update group of the plurality of update groups and assign an update frequency to the update group based on the set of model maintenance parameters, such that the update frequency corresponds to an activation rate of periodic update events for broadcasting updated data samples for the data analysis model to the member user devices. In some embodiments, the set of model maintenance parameters includes a hardware specification of the user device, a software requirement for an application of the user device, a data format associated with the data analysis model, or a set of parameters corresponding to output data of the data analysis model.

In further embodiments, the network system can include a minimum viable frequency predictor that can be used to assign the update frequency of each update group of the plurality of update groups by receiving a set of available update frequencies for the update group, determining (e.g., via the minimum viable frequency predictor) a minimum viable frequency for the update group, such that the minimum viable frequency corresponds to a minimum required activation rate of periodic update events for broadcasting updated data samples for the data analysis model to member user devices of the update group and the minimum viable frequency predictor infers the minimum viable frequency using the set of model maintenance parameters for the member user devices. Further, the network system can assign a selected update frequency from the set of available update frequencies to the update group that is closest to the minimum viable frequency.

In additional, or alternative embodiments, the network system can receive a first update frequency of a first update group of the plurality of update groups such that the first update frequency corresponds to a first activation rate of periodic update events for broadcasting updated data samples for the data analysis model to member user devices of the first update group. Similarly, the network system can receive a second update frequency of a second update group of the plurality of update groups such that the second update frequency corresponds to a second activation rate of periodic update events for broadcasting updated data samples for the data analysis model to member user devices of the second update group and a difference measure between the first and the second update frequencies is within a similarity threshold. As such, the network system can determine a third update frequency based on the first and the second update frequencies such that the third update frequency corresponds to a third activation rate of periodic update events for broadcasting update data samples for the data analysis model to member user devices of both the first and the second update groups and reassign member user devices of both the first and the second update groups to a third update group of the plurality of update groups such that the third update group is assigned the third update frequency.

At 530, the network system can detect an update event for the data analysis model such that the update event is activated when a time duration since a previous data analysis model update reaches a duration threshold, and the duration threshold is a period of an update frequency.

At 540, the network system can selectively broadcast updated data samples for the data analysis model to user devices in a first update group of the plurality of update groups in response to detecting the update event.

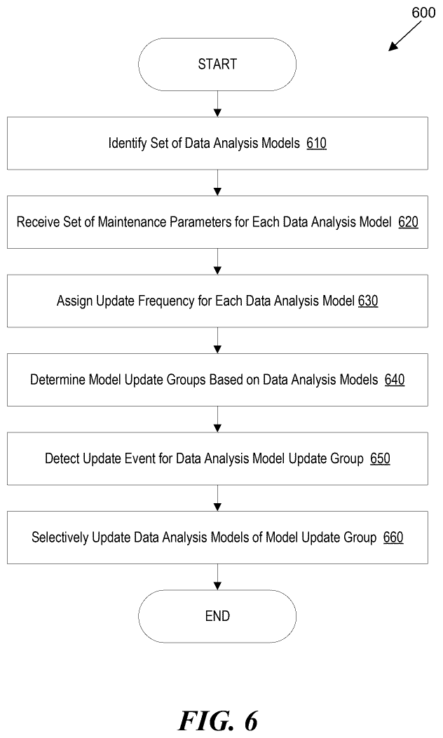

FIG. 6 is a flow diagram that illustrates another process to configure a network system in some implementations. The process 600 can be performed by a system (e.g., a network system) configured to minimize overhead data transfer of model training samples to UE devices of a telecommunications network. In one example, the network system includes at least one hardware processor and at least one non-transitory memory storing instructions, which, when executed by the at least one hardware processor, cause the network system to perform the process 600. In another example, the network system a non-transitory, computer-readable storage medium comprising instructions recorded thereon, which the instructions when executed by at least one data processor of a network system, cause the network system to perform the process 600.

At 610, the network system can identify a set of data analysis models where each data analysis model is usable by a user device communicatively that is coupled to the network server via a telecommunications network to control performance of the user device on the telecommunications network. For example, the network system can identify one or more data analysis models for computing channel state information (CSI), a model for performing beamforming, or a model based on a machine learning architecture.

At 620, the network system can receive a set of model maintenance parameters for each data analysis model in the set of data analysis models, such that the set of model maintenance parameters includes a hardware specification of the user device, a software requirement for an application of the user device, a data format associated with the data analysis model, or a set of parameters corresponding to output data of the data analysis model.

At 630, the network system can assign an update frequency for each data analysis model in the set of data analysis models based on the set of model maintenance parameters of the data analysis model. For example, the network system can assign an update frequency to the data analysis model based on the set of model maintenance parameters, such that the update frequency corresponds to an activation rate of periodic update events for broadcasting updated data samples for updating the data analysis model.

At 640, the network system can determine a set of model update groups based on the set of data analysis models where each model update group has a group update frequency and comprises one or more data analysis models with update frequencies that are within a frequency threshold of the group update frequency and one or more user devices are assigned to each model update group.

At 650, the network system can detect an update event for at least one model update group from the set of model update groups, such that the update event is activated when a time duration since a previous update event for the at least one model update group reaches a duration threshold, the duration threshold corresponding to a period of an update frequency.

At 660, the network system can selectively update data analysis models used by the user devices assigned to the at least one model update group in response to detecting the update event by broadcasting updated data samples for the data analysis models to the user devices.

### Computer System

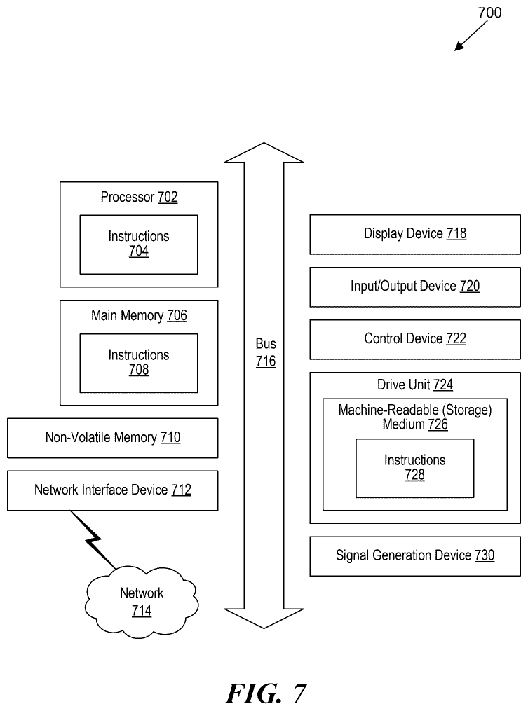

FIG. 7 is a block diagram that illustrates an example of a computer system 700 in which at least some operations described herein can be implemented. As shown, the computer system 700 can include: one or more processors 702, main memory 706, non-volatile memory 710, a network interface device 712, a video display device 718, an input/output device 720, a control device 722 (e.g., keyboard and pointing device), a drive unit 724 that includes a machine-readable (storage) medium 726, and a signal generation device 730 that are communicatively connected to a bus 716. The bus 716 represents one or more physical buses and/or point-to-point connections that are connected by appropriate bridges, adapters, or controllers. Various common components (e.g., cache memory) are omitted from FIG. 7 for brevity. Instead, the computer system 700 is intended to illustrate a hardware device on which components illustrated or described relative to the examples of the figures and any other components described in this specification can be implemented.

The computer system 700 can take any suitable physical form. For example, the computing system 700 can share a similar architecture as that of a server computer, personal computer (PC), tablet computer, mobile telephone, game console, music player, wearable electronic device, network-connected (“smart”) device (e.g., a television or home assistant device), AR/VR systems (e.g., head-mounted display), or any electronic device capable of executing a set of instructions that specify action(s) to be taken by the computing system 700. In some implementations, the computer system 700 can be an embedded computer system, a system-on-chip (SOC), a single-board computer system (SBC), or a distributed system such as a mesh of computer systems, or it can include one or more cloud components in one or more networks. Where appropriate, one or more computer systems 700 can perform operations in real time, in near real time, or in batch mode.

The network interface device 712 enables the computing system 700 to mediate data in a network 714 with an entity that is external to the computing system 700 through any communication protocol supported by the computing system 700 and the external entity. Examples of the network interface device 712 include a network adapter card, a wireless network interface card, a router, an access point, a wireless router, a switch, a multilayer switch, a protocol converter, a gateway, a bridge, a bridge router, a hub, a digital media receiver, and/or a repeater, as well as all wireless elements noted herein.

The memory (e.g., main memory 706, non-volatile memory 710, machine-readable medium 726) can be local, remote, or distributed. Although shown as a single medium, the machine-readable medium 726 can include multiple media (e.g., a centralized/distributed database and/or associated caches and servers) that store one or more sets of instructions 728. The machine-readable medium 726 can include any medium that is capable of storing, encoding, or carrying a set of instructions for execution by the computing system 700. The machine-readable medium 726 can be non-transitory or comprise a non-transitory device. In this context, a non-transitory storage medium can include a device that is tangible, meaning that the device has a concrete physical form, although the device can change its physical state. Thus, for example, non-transitory refers to a device remaining tangible despite this change in state.

Although implementations have been described in the context of fully functioning computing devices, the various examples are capable of being distributed as a program product in a variety of forms. Examples of machine-readable storage media, machine-readable media, or computer-readable media include recordable-type media such as volatile and non-volatile memory 710, removable flash memory, hard disk drives, optical disks, and transmission-type media such as digital and analog communication links.

In general, the routines executed to implement examples herein can be implemented as part of an operating system or a specific application, component, program, object, module, or sequence of instructions (collectively referred to as “computer programs”). The computer programs typically comprise one or more instructions (e.g., instructions 704, 708, 728) set at various times in various memory and storage devices in computing device(s). When read and executed by the processor 702, the instruction(s) cause the computing system 700 to perform operations to execute elements involving the various aspects of the disclosure.

### Remarks

The terms “example,” “embodiment,” and “implementation” are used interchangeably. For example, references to “one example” or “an example” in the disclosure can be, but not necessarily are, references to the same implementation; and such references mean at least one of the implementations. The appearances of the phrase “in one example” are not necessarily all referring to the same example, nor are separate or alternative examples mutually exclusive of other examples. A feature, structure, or characteristic described in connection with an example can be included in another example of the disclosure. Moreover, various features are described that can be exhibited by some examples and not by others. Similarly, various requirements are described that can be requirements for some examples but not for other examples.

The terminology used herein should be interpreted in its broadest reasonable manner, even though it is being used in conjunction with certain specific examples of the invention. The terms used in the disclosure generally have their ordinary meanings in the relevant technical art, within the context of the disclosure, and in the specific context where each term is used. A recital of alternative language or synonyms does not exclude the use of other synonyms. Special significance should not be placed upon whether or not a term is elaborated or discussed herein. The use of highlighting has no influence on the scope and meaning of a term. Further, it will be appreciated that the same thing can be said in more than one way.

Unless the context clearly requires otherwise, throughout the description and the claims, the words “comprise,” “comprising,” and the like are to be construed in an inclusive sense, as opposed to an exclusive or exhaustive sense—that is to say, in the sense of “including, but not limited to.” As used herein, the terms “connected,” “coupled,” and any variants thereof mean any connection or coupling, either direct or indirect, between two or more elements; the coupling or connection between the elements can be physical, logical, or a combination thereof. Additionally, the words “herein,” “above,” “below,” and words of similar import can refer to this application as a whole and not to any particular portions of this application. Where context permits, words in the above Detailed Description using the singular or plural number may also include the plural or singular number, respectively. The word “or” in reference to a list of two or more items covers all of the following interpretations of the word: any of the items in the list, all of the items in the list, and any combination of the items in the list. The term “module” refers broadly to software components, firmware components, and/or hardware components.

While specific examples of technology are described above for illustrative purposes, various equivalent modifications are possible within the scope of the invention, as those skilled in the relevant art will recognize. For example, while processes or blocks are presented in a given order, alternative implementations can perform routines having steps, or employ systems having blocks, in a different order, and some processes or blocks may be deleted, moved, added, subdivided, combined, and/or modified to provide alternative or sub-combinations. Each of these processes or blocks can be implemented in a variety of different ways. Also, while processes or blocks are at times shown as being performed in series, these processes or blocks can instead be performed or implemented in parallel, or can be performed at different times. Further, any specific numbers noted herein are only examples such that alternative implementations can employ differing values or ranges.

Details of the disclosed implementations can vary considerably in specific implementations while still being encompassed by the disclosed teachings. As noted above, particular terminology used when describing features or aspects of the invention should not be taken to imply that the terminology is being redefined herein to be restricted to any specific characteristics, features, or aspects of the invention with which that terminology is associated. In general, the terms used in the following claims should not be construed to limit the invention to the specific examples disclosed herein, unless the above Detailed Description explicitly defines such terms. Accordingly, the actual scope of the invention encompasses not only the disclosed examples but also all equivalent ways of practicing or implementing the invention under the claims. Some alternative implementations can include additional elements to those implementations described above or include fewer elements.

Any patents and applications and other references noted above, and any that may be listed in accompanying filing papers, are incorporated herein by reference in their entireties, except for any subject matter disclaimers or disavowals, and except to the extent that the incorporated material is inconsistent with the express disclosure herein, in which case the language in this disclosure controls. Aspects of the invention can be modified to employ the systems, functions, and concepts of the various references described above to provide yet further implementations of the invention.

To reduce the number of claims, certain implementations are presented below in certain claim forms, but the applicant contemplates various aspects of an invention in other forms. For example, aspects of a claim can be recited in a means-plus-function form or in other forms, such as being embodied in a computer-readable medium. A claim intended to be interpreted as a means-plus-function claim will use the words “means for.” However, the use of the term “for” in any other context is not intended to invoke a similar interpretation. The applicant reserves the right to pursue such additional claim forms either in this application or in a continuing application.

We claim:

1. A network system comprising:
at least one hardware processor; and
at least one non-transitory memory storing instructions, which, when executed by the at least one hardware processor, cause the network system to:
provide a data analysis model to multiple user devices that are communicatively coupled to the network system via a telecommunications network,
wherein the data analysis model is usable by the multiple user devices to control performance of the multiple user devices on the telecommunications network;
assign each of the multiple user devices to a selected update group of a plurality of update groups,
wherein a respective user device is assigned to a corresponding selected update group based on a set of device environment parameters of the respective user device;
detect an update event for the data analysis model; and
in response to detecting the update event, selectively broadcast updated data samples for the data analysis model to user devices in a first update group of the plurality of update groups.

2. The network system of claim 1 further caused to:
for each update group of the plurality of update groups:
receive a set of model maintenance parameters for member user devices of the update group of the plurality of update groups, and
assign an update frequency to the update group based on the set of model maintenance parameters,
wherein the update frequency corresponds to an activation rate of periodic update events for broadcasting updated data samples for the data analysis model to the member user devices.

3. The network system of claim 2,
wherein the update frequency of each update group of the plurality of update groups is assigned by further causing the network system to:
receive a set of available update frequencies for the update group;
determine, using a minimum viable frequency predictor, a minimum viable frequency for the update group,
wherein the minimum viable frequency corresponds to a minimum required activation rate of periodic update events for broadcasting updated data samples for the data analysis model to member user devices of the update group, and
wherein the minimum viable frequency predictor infers the minimum viable frequency using the set of model maintenance parameters for the member user devices; and
assign a selected update frequency from the set of available update frequencies to the update group that is closest to the minimum viable frequency.

4. The network system of claim 1 further caused to:
receive a first update frequency of a first update group of the plurality of update groups,
wherein the first update frequency corresponds to a first activation rate of periodic update events for broadcasting updated data samples for the data analysis model to member user devices of the first update group;
receive a second update frequency of a second update group of the plurality of update groups,
wherein the second update frequency corresponds to a second activation rate of periodic update events for broadcasting updated data samples for the data analysis model to member user devices of the second update group, and
wherein a difference measure between the first and the second update frequencies is within a similarity threshold;
determine a third update frequency based on the first and the second update frequencies,
wherein the third update frequency corresponds to a third activation rate of periodic update events for broadcasting update data samples for the data analysis model to member user devices of both the first and the second update groups; and
reassign member user devices of both the first and the second update groups to a third update group of the plurality of update groups,
wherein the third update group is assigned the third update frequency.

5. The network system of claim 1 further caused to:
detect an update in the set of device environment parameters of the respective user device; and
in response to the detected update, assign the respective user device to a different update group from the plurality of update groups based on the updated set of device environment parameters.

6. The network system of claim 1 further caused to:
provide a second data analysis model to a selected user device of the multiple user devices communicatively coupled to the network system via a telecommunications network,
wherein the second data analysis model is usable by the selected user device to control performance of the selected user device on the telecommunications network; and
assign the selected user device to a second selected update group of the plurality of update groups,
wherein the selected user device is assigned to the second selected update group based on a second set of device environment parameters, and
wherein the second selected update group is different from the selected update group already assigned to the selected user device.

7. The network system of claim 1, wherein the set of device environment parameters includes a location of the user device, a change in the location of the user device, a communication quality measure between the user device and the network system, a measure of network traffic at the network system, or any combination thereof.

8. The network system of claim 2, wherein the set of model maintenance parameters includes a hardware specification of the user device, a software requirement for an application of the user device, a data format associated with the data analysis model, a set of parameters corresponding to output data of the data analysis model, or any combination thereof.

9. The network system of claim 1, wherein the data analysis model includes a model for computing channel state information (CSI), a model for performing beamforming, or a model based on a machine learning architecture.

10. The network system of claim 1, wherein the update event is activated when a time duration since a previous data analysis model update reaches a duration threshold, and wherein the duration threshold is a period of an update frequency.

11. The network system of claim 1 further caused to:
determine a set of candidate update groups from the plurality of update groups that the respective user device can be assigned to,
wherein each candidate update group in the set of candidate update group has an associated update frequency; and
add the respective user device to a selected candidate update group from the set of candidate update groups,
wherein the selected candidate update group has a minimum associated update frequency within the set of candidate update groups, and
wherein adding the respective user device to the selected candidate update group with the minimum associated update frequency results in a reduction of greenhouse gas emissions.

12. A non-transitory, computer-readable storage medium comprising instructions recorded thereon, wherein the instructions when executed by at least one data processor of a network system, cause the network system to:
provide a data analysis model to multiple user devices that are communicatively coupled to the network system via a telecommunications network,
wherein the data analysis model is usable by the multiple user devices to control performance of the multiple user devices on the telecommunications network;
assign each of the multiple user devices to a selected update group of a plurality of update groups,
wherein a respective user device is assigned to a corresponding selected update group based on a set of device environment parameters of the respective user device;
detect an update event for the data analysis model; and
in response to detecting the update event, selectively broadcast updated data samples for the data analysis model to user devices in a first update group of the plurality of update groups.

13. The non-transitory, computer-readable medium of claim 11, wherein the instructions further cause the network system to:
for each update group of the plurality of update groups:
receive a set of model maintenance parameters for member user devices of the update group of the plurality of update groups, and
assign an update frequency to the update group based on the set of model maintenance parameters,
wherein the update frequency corresponds to an activation rate of periodic update events for broadcasting updated data samples for the data analysis model to the member user devices.

14. The non-transitory, computer-readable medium of claim 12, the update frequency of each update group of the plurality of update groups is assigned by further causing the network system to:
access a minimum viable frequency predictor;
receive a set of available update frequencies for the update group;
determine, using the minimum viable frequency predictor, a minimum viable frequency for the update group,
wherein the minimum viable frequency corresponds to a minimum required activation rate of periodic update events for broadcasting updated data samples for the data analysis model to member user devices of the update group, and
wherein the minimum viable frequency predictor infers the minimum viable frequency using the set of model maintenance parameters for the member user devices; and
assign a selected update frequency from the set of available update frequencies to the update group that is closest to the minimum viable frequency.

15. The non-transitory, computer-readable medium of claim 11, wherein the instructions further cause the network system to:
receive a first update frequency of a first update group of the plurality of update groups,
wherein the first update frequency corresponds to a first activation rate of periodic update events for broadcasting updated data samples for the data analysis model to member user devices of the first update group;
receive a second update frequency of a second update group of the plurality of update groups,
wherein the second update frequency corresponds to a second activation rate of periodic update events for broadcasting updated data samples for the data analysis model to member user devices of the second update group, and
wherein a difference measure between the first and the second update frequencies is within a similarity threshold;
determine a third update frequency based on the first and the second update frequencies,
wherein the third update frequency corresponds to a third activation rate of periodic update events for broadcasting update data samples for the data analysis model to member user devices of both the first and the second update groups; and
reassign member user devices of both the first and the second update groups to a third update group of the plurality of update groups,
wherein the third update group is assigned the third update frequency.

16. The non-transitory, computer-readable medium of claim 11, wherein the instructions further cause the network system to:
detect an update in the set of device environment parameters of the respective user device; and
in response to the detected update, assign the respective user device to a different update group from the plurality of update groups based on the updated set of device environment parameters.

17. The non-transitory, computer-readable medium of claim 11, wherein the instructions further cause the network system to:
provide a second data analysis model to a selected user device of the multiple user devices communicatively coupled to the network system via a telecommunications network,
wherein the second data analysis model is usable by the selected user device to control performance of the selected user device on the telecommunications network; and
assign the selected user device to a second selected update group of the plurality of update groups,
wherein the selected user device is assigned to the second selected update group based on a second set of device environment parameters, and
wherein the second selected update group is different from the selected update group already assigned to the selected user device.

18. The non-transitory, computer-readable medium of claim 11, wherein the set of device environment parameters includes a location of the user device, a change in the location of the user device, a communication quality measure between the user device and the network system, a measure of network traffic at the network system, or any combination thereof.

19. The non-transitory, computer-readable medium of claim 12, wherein the set of model maintenance parameters includes a hardware specification of the user device, a software requirement for an application of the user device, a data format associated with the data analysis model, a set of parameters corresponding to output data of the data analysis model, or any combination thereof.

20. A computer-implemented method, the method comprising:
identifying, at a network server, a set of data analysis models,
wherein each data analysis model is usable by a user device communicatively coupled to the network server via a telecommunications network to control performance of the user device on the telecommunications network;
for each data analysis model in the set of data analysis models:
receiving, at the network server, a set of model maintenance parameters, and
assigning, at the network server, an update frequency for the data analysis model based on the set of model maintenance parameters;
determining, at the network server, a set of model update groups based on the set of data analysis models,
wherein each model update group has a group update frequency and comprises one or more data analysis models with update frequencies that are within a frequency threshold of the group update frequency, and
wherein one or more user devices are assigned to each model update group;
detecting, at the network server, an update event for at least one model update group from the set of model update groups; and
in response to detecting the update event, selectively updating data analysis models used by the user devices assigned to the at least one model update group.
